(19) United States
(12) Patent Application Publication
(10) Pub. No.: US 2024/0278966 A1
(43) Pub. Date: Aug. 22, 2024

(54) GAS BARRIER LAMINATE, PACKAGING BODY AND PACKAGED ARTICLE

(71) Applicant: TOPPAN HOLDINGS INC., Tokyo (JP)

(72) Inventor: Sayaka HOSHI, Tokyo (JP)

(73) Assignee: TOPPAN HOLDINGS INC., Tokyo (JP)

(21) Appl. No.: 18/645,060

(22) Filed: Apr. 24, 2024

(30) Foreign Application Priority Data
Oct. 26, 2021 (JP) 2021-174684

(51) Int. Cl. B65D 65/42; C09D 7/61; C09D 133/02; C23C 16/02; C23C 16/40

(52) U.S. Cl. CPC B65D 65/42; C09D 7/61; C09D 133/02; C23C 16/02; C23C 16/403; B65D 2565/387

(57) ABSTRACT

A gas barrier laminate includes a substrate, an inorganic vapor deposition layer containing an inorganic oxide, and a coating layer, which are laminated in this order, the coating layer being composed of a single layer or a plurality of layers. The coating layer contains a carboxy group-containing polymer, and at least one type of polyvalent metal-containing particles, a total X-ray fluorescence intensity of metal elements contained in the polyvalent metal-containing particles is 3.0 kcps or greater and 8.0 kcps or less, and an absorbance X of the gas barrier laminate 10 obtained by subtracting an absorbance X₂ at a wavelength of 500 nm from an absorbance X₁ at a wavelength of 350 nm measured with an ultraviolet-visible spectrophotometer after hot water treatment at 130° C. for 30 minutes using a 0.3 mass % L-cysteine aqueous solution satisfies the following formula: X=X₁−X₂≥0.02 (abs).

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2022/038919, filed on Oct. 19, 2022, which is based upon and claims the benefit to Japanese Patent Application No. 2021-174684 filed on Oct. 26, 2021, the disclosures of which are incorporated herein by reference in their entirety.

### TECHNICAL FIELD

The present invention relates to gas barrier laminates, packaging bodies and packaged articles.

### BACKGROUND

Packaging materials used for packaging foods, pharmaceuticals, cosmetics, agricultural chemicals, industrial products, and the like are required to prevent deterioration of the contents. For example, packaging materials for foods are required to have a deterioration prevention function that reduces oxidation or degradation of protein, oil and fat, or the like and preserves flavor and freshness. Such deterioration of the contents is mainly caused by oxygen or water vapor permeating through the packaging material or by other gases reactive to the contents. Therefore, packaging materials having properties that do not allow permeation of gases such as oxygen and water vapor (gas barrier properties) have been developed.

For example, PTLs 1 to 3 disclose a laminate including a coating layer containing a carboxylic acid polymer and a polyvalent metal compound, in which at least part of the —COO— groups contained in the carboxylic acid polymer is crosslinked by polyvalent metal ions, thereby providing gas barrier properties. Such a gas barrier laminate has excellent gas barrier properties even in high humidity atmospheres and can be used in packaging applications which involve moist heat treatment such as boiling or retort treatment.

[Citation List] [Patent Literature] PTL 1: JP 5278802 B; PTL 2: JP 2016-193509 A; PTL 3: WO 2016/158444.

### SUMMARY OF THE INVENTION

When the contents such as foods are filled into the packaging body, which is then subjected to moist heat treatment such as retort treatment or boiling treatment, substances generated from the contents may permeate the packaging material, adversely affecting the gas barrier properties. For example, when the contents in the packaging body contain sulfur, a sulfur component is generated from the contents during moist heat treatment. This causes a problem that the sulfur permeates the packaging material, and reduces, in particular, the oxygen barrier properties.

The present invention has been made to provide a gas barrier laminate capable of maintaining high oxygen barrier properties after moist heat treatment such as retort treatment or boiling treatment and, even when the contents contain sulfur, suppressing deterioration of oxygen barrier properties caused by permeation of sulfur during moist heat treatment, and provide a packaging body and a packaged article including the gas barrier laminate.

The above problem of reduced oxygen barrier properties is known to occur when sulfur generated from the contents during moist heat treatment such as retort treatment reacts and bonds with polyvalent metal ions of a polyvalent metal compound bonded to the carboxy group-containing polymer, destroying the crosslinked structure. According to an embodiment of the present invention, sulfur generated from the contents during moist heat treatment is prevented from bonding with polyvalent metal ions of the polyvalent metal compound bonded to the carboxy group-containing polymer, preventing destruction of a crosslinked structure by sulfur and maintaining high oxygen barrier properties.

That is, according to a first aspect of the present invention, there is provided a gas barrier laminate including: a substrate; an inorganic vapor deposition layer containing an inorganic oxide; and a coating layer, which are laminated in this order, the coating layer being composed of a single layer or a plurality of layers, wherein the coating layer contains a carboxy group-containing polymer and at least one type of polyvalent metal-containing particles, a total X-ray fluorescence intensity of metal elements contained in the polyvalent metal-containing particles is 3.0 kcps or greater and 8.0 kcps or less, and an absorbance X of the gas barrier laminate obtained by subtracting an absorbance X₂ at a wavelength of 500 nm from an absorbance X₁ at a wavelength of 350 nm measured with an ultraviolet-visible spectrophotometer after hot water treatment at 130° C. for 30 minutes using a 0.3 mass % L-cysteine aqueous solution satisfies the following formula (1):

X=X₁−X₂≥0.02(abs) (1)

According to a second aspect of the present invention, there is provided a packaging body including the laminate according to the first aspect.

According to a third aspect of the present invention, there is provided a packaged article including: the packaging body according to the second aspect; and contents contained in the packaging body.

### Advantageous Effects of Invention

The present invention has been made to provide a gas barrier laminate capable of maintaining high oxygen barrier properties after moist heat treatment such as retort treatment or boiling treatment and, even when the contents contain sulfur, suppressing deterioration of oxygen barrier properties caused by permeation of sulfur during moist heat treatment, and provide a packaging body and a packaged article including the gas barrier laminate.

### BRIEF DESCRIPTION OF THE DRAWINGS

FIG. 1 is a cross-sectional view schematically illustrating a laminate according to an embodiment of the present invention.

FIG. 2 is a cross-sectional view schematically illustrating a laminate according to another embodiment of the present invention.

### DETAILED DESCRIPTION

With reference to the drawings, some embodiments of the present invention will be described. The embodiments described below are more specific examples of any of the aspects described above.

In the present disclosure, the description “AA is on BB” is used regardless of the direction of gravity. The situation specified by the description “AA is on BB” encompasses the situation in which AA is in contact with BB. The description “AA is on BB” does not exclude one or more components being interposed between AA and BB.

### <Gas Barrier Laminate>

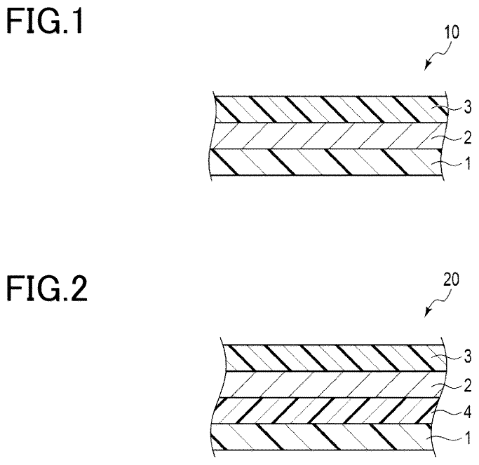

FIG. 1 is a cross-sectional view schematically illustrating a gas barrier laminate according to an embodiment of the present invention.

A gas barrier laminate 10 shown in FIG. 1 includes a substrate 1, an inorganic vapor deposition layer 2 containing an inorganic oxide, and a coating layer 3, which are laminated in this order. The coating layer 3 is a single layer or a laminate unit composed of a plurality of layers (not shown) and contains a carboxy group-containing polymer (a) and at least one type of polyvalent metal-containing particles (b).

In the gas barrier laminate 10, a total X-ray fluorescence intensity of metal elements contained in the polyvalent metal-containing particles (b) contained in the coating layer 3 is 3.0 kcps or greater and 8.0 kcps or less, and an absorbance X obtained by subtracting an absorbance X₂ at a wavelength of 500 nm from an absorbance X₁ at a wavelength of 350 nm measured with an ultraviolet-visible spectrophotometer after hot water treatment at 130° C. for 30 minutes using a 0.3 mass % L-cysteine aqueous solution satisfies the following formula (1).

$$X = {X}_{1} - {X}_{2} \geq 0.02 ( abs ) \qquad ( 1 )$$

Polyvalent metal ions generated from the polyvalent metal-containing particles contained in the coating layer 3 react with the carboxy group-containing polymer (a). In this case, a crosslinked structure is formed in which the carboxy group-containing polymer (a) is ionically crosslinked via the polyvalent metal ions. This improves the oxygen barrier properties of the coating layer 3, so the gas barrier laminate 10 exhibits excellent oxygen barrier properties. Here, when sulfur generated from the contents during moist heat treatment such as retort treatment or boiling treatment permeates the packaging material, the polyvalent metal ions constituting the above crosslinked structure of the coating layer 3 react with sulfur ions. In this case, in conventional gas barrier laminates, the above crosslinked structure is destroyed, leading to a problem of reduced oxygen barrier properties.

On the other hand, in the gas barrier laminate 10 according to the present embodiment, as described above, the total X-ray fluorescence intensity of metal elements of the polyvalent metal-containing particles (b) contained in the coating layer 3 is 3.0 kcps or greater and 8.0 kcps or less, and the absorbance X measured after the above hot water treatment is 0.02 abs or greater. When all of these conditions are satisfied, in the coating layer 3, the crosslinked structure of the carboxy group-containing polymer (a) is formed via the polyvalent metal ions during the moist heat treatment, and excess polyvalent metal ions that are not involved in the crosslinked structure are present.

The excess polyvalent metal ions as referred to herein refers to the excess of polyvalent metal ions relative to the required polyvalent metal ions to form a crosslinked structure with the carboxy group-containing polymer (a). Therefore, when sulfur generated from the contents permeates the gas barrier laminate which is a packaging material during moist heat treatment, the excess polyvalent metal ions present in the coating layer 3 chemically react with the sulfur. As a result, destruction of the crosslinked structure due to sulfur can be suppressed.

As described above, even when the contents contain sulfur, the gas barrier laminate 10 according to the present embodiment can suppress the adverse effects of the sulfur permeating the laminate during moist heat treatment and destroying the crosslinked structure. Therefore, using the gas barrier laminate 10 according to the present embodiment as a packaging material can maintain high oxygen barrier properties after moist heat treatment such as retort treatment or boiling treatment even when the contents of the packaging body contain sulfur such as sulfur-containing amino acids.

The absorbance X is the ultraviolet absorbance (UV absorbance) measured using an ultraviolet-visible spectrophotometer and corresponds to a value (abs) obtained by subtracting the absorbance X₂ at the wavelength of 500 nm from the absorbance X₁ at the wavelength of 350 nm measured for the gas barrier laminate after hot water treatment. The hot water treatment condition is a retort treatment of a hot water storage type at 130° C. for 30 minutes using a 0.3 mass % L-cysteine aqueous solution.

Further, although sulfur generated from the contents during the moist heat treatment such as retort treatment is accompanied by an unpleasant odor called a retort odor, the sulfur chemically reacts with the excess polyvalent metal ions present in the coating layer 3 and is retained in the gas barrier laminate, preventing the packaging body from being filled with the retort odor.

Each layer included in the gas barrier laminate 10 according to the present embodiment will be described below.

### <Coating Layer>

The coating layer 3 contains the carboxy group-containing polymer (a) and the polyvalent metal-containing particles (b), which will be described in detail below. The coating layer 3 may further contain a surfactant, a silicon-containing compound, and the like.

As described above, in the gas barrier laminate 10 according to the present embodiment, the total X-ray fluorescence intensity of metal elements of the polyvalent metal-containing particles (b) contained in the coating layer 3 is 3.0 kcps or greater and 8.0 kcps or less, and the absorbance X measured after the hot water treatment is 0.02 abs or greater. When these conditions are satisfied, in the coating layer 3, the crosslinked structure of the carboxy group-containing polymer (a) is formed via the polyvalent metal ions during the moist heat treatment, and excess polyvalent metal ions that are not involved in the crosslinked structure are present.

By measuring the X-ray fluorescence intensity of each element contained in the coating layer 3, each element can be quantitatively analyzed. In the present embodiment, when the total X-ray fluorescence intensity of the metal elements derived from the polyvalent metal-containing particles contained in the coating layer 3 is 3.0 kcps or greater, the ionically crosslinked structure formed by the carboxy group-containing polymer (a) via the polyvalent metal ions exhibits excellent oxygen barrier properties.

On the other hand, when the total X-ray fluorescence intensity of the metal elements contained in the coating layer 3 exceeds 8.0 kcp, the film strength becomes weak and the oxygen barrier properties are reduced.

In addition, when one type of polyvalent metal-containing particles (b) is contained in the coating layer 3, the total X-ray fluorescence intensity means the X-ray fluorescence intensity of a single type of polyvalent metal-containing particles (b). When the coating layer 3 contains only one type of zinc compound as the polyvalent metal-containing particles (b), the X-ray fluorescence intensity is preferably 4.0 kcps or greater.

In the gas barrier laminate 10, the more the polyvalent metal-containing particles (b) that are not bonded to the carboxy group-containing polymer (a), the higher the UV absorbance tends to be. In the present embodiment, when the absorbance X is 0.02 or greater, excess polyvalent metal ions that are not bonded to the carboxy group-containing polymer (a) can be present in the coating layer 3, and, when sulfur generated from the contents permeates the coating layer 3 during moist heat treatment, the sulfur chemically reacts with the excess polyvalent metal ions as described above. As a result, destruction of the crosslinked structure due to sulfur can be suppressed, and high oxygen barrier properties can be maintained.

In the present embodiment, the absorbance X of the gas barrier laminate 10 is 0.02 or greater. On the other hand, the upper limit of the absorbance X of the gas barrier laminate 10 is not particularly limited as long as it is lower than the absorbance before hot water treatment. According to one example, the upper limit of the absorbance X can be appropriately set from the viewpoint of the crosslinking ratio of the —COO— groups contained in the carboxy group-containing polymer (a), and may be, for example, 0.4 or less.

The coating layer 3 may be a single layer or may be a laminate unit composed of a plurality of layers. When the coating layer 3 is composed of a plurality of layers, the carboxy group-containing polymer (a) and the polyvalent metal-containing particles (b) may be contained in the same layer or may be contained in different layers.

As an example of a case where the coating layer 3 is composed of a plurality of layers, the coating layer 3 may include a laminate unit in which a first coating layer containing the carboxy group-containing polymer (a) and a second coating layer containing the polyvalent metal-containing particles (b) are adjacent to each other. In one example, the first coating layer and the second coating layer are preferably laminated in this order from the inorganic vapor deposition layer 2 side.

In this case, at least part of the polyvalent metal ions generated from the polyvalent metal-containing particles (b) included in the second coating layer diffuses into the first coating layer during moist heat treatment. When the contents contain sulfur, part of sulfur generated from the contents during moist heat treatment chemically reacts with the polyvalent metal-containing particles (b) of the second coating layer, but the remaining sulfur may reach the first coating layer. The gas barrier laminate 10 according to the present embodiment satisfies all the above conditions regarding the UV absorbance X and the X-ray fluorescence intensity. Therefore, among the polyvalent metal ions diffused into the first coating layer during moist heat treatment, the required amount of polyvalent metal ions forms a crosslinked structure, and the excess polyvalent metal ions chemically react with the sulfur reaching the first coating layer to suppress destruction of the crosslinked structure due to sulfur.

The first coating layer may further contain the polyvalent metal-containing particles (b). In this case, the polyvalent metal-containing particles (b) contained in the first coating layer may be the same as or different from the polyvalent metal-containing particles (b) contained in the second coating layer. Specific examples of the polyvalent metal-containing particles (b) contained in the first coating layer and the second coating layer can be appropriately selected from the specific examples described later. The examples include zinc compounds and calcium compounds.

[Carboxy Group-Containing Polymer (a)]

The carboxy group-containing polymer (a) contained in the coating layer 3 is a polymer having two or more carboxy groups in the molecule, and may be hereinafter referred to as a “polycarboxylic acid polymer.” As described above, the carboxy group-containing polymer (a) is ionically crosslinked, in the coating layer 3, with metal ions derived from the polyvalent metal-containing particles (b), which will be described later, and exhibit excellent gas barrier properties. Typical examples of the carboxy group-containing polymer (a) include a homopolymer of a carboxy group-containing unsaturated monomer, a copolymer of two or more carboxy group-containing unsaturated monomers, a copolymer of a carboxy group-containing unsaturated monomer and other polymerizable monomers, and polysaccharides containing carboxy groups in the molecule (also referred to as “carboxy group-containing polysaccharides” or “acidic polysaccharides”).

The carboxy group includes not only a free carboxy group, but also an acid anhydride group (specifically, a dicarboxylic acid anhydride group). The acid anhydride group may be partially ring-opened to form a carboxy group. Part of the carboxy groups may be neutralized with an alkali. In this case, the degree of neutralization is preferably 20% or less.

The “degree of neutralization” is a value obtained by the following method. That is, by adding an alkali (ft) to the carboxy group-containing polymer (a), the carboxy groups can be partially neutralized. The degree of neutralization is a ratio of the molar amount (ft) of alkali (f) to the molar amount (at) of carboxy groups contained in the carboxy group-containing polymer (a).

In addition, a graft polymer obtained by graft-polymerizing a carboxy group-containing unsaturated monomer with a polymer that does not contain a carboxy group, such as polyolefin, can also be used as the carboxy group-containing polymer (a). A polymer with a hydrolyzable ester group such as an alkoxycarbonyl group (e.g., methoxycarbonyl group), which is converted to a carboxy group by hydrolysis, can also be used.

As the carboxy group-containing unsaturated monomer, it is preferred to use α,β-monoethylenically unsaturated carboxylic acid. Therefore, examples of the carboxy group-containing polymer (a) include a homopolymer of α,β-monoethylenically unsaturated carboxylic acid, a copolymer of two or more α,β-monocthylenically unsaturated carboxylic acid, and a copolymer of α,β-monoethylenically unsaturated carboxylic acid and other polymerizable monomers. Typical example of the other polymerizable monomers include ethylenically unsaturated monomers.

Examples of the α,β-monoethylenically unsaturated carboxylic acid include unsaturated monocarboxylic acids such as acrylic acid, methacrylic acid and crotonic acid; unsaturated dicarboxylic acids such as maleic acid, fumaric acid and itaconic acid; unsaturated dicarboxylic acid anhydrides such as maleic anhydride and itaconic anhydride; and mixtures of two or more thereof. Among these, at least one α,β-monoethylenically unsaturated carboxylic acid selected from the group consisting of acrylic acid, methacrylic acid, crotonic acid, maleic acid, fumaric acid and itaconic acid is preferred, and at least one α,β-monoethylenically unsaturated carboxylic acid selected from the group consisting of acrylic acid, methacrylic acid and maleic acid is more preferred.

Examples of other polymerizable monomers copolymerizable with α,β-monoethylenically unsaturated carboxylic acid, especially ethylenically unsaturated monomer include ethylene; α-olefins such as propylene, 1-butene, 1-pentene, 1-hexene and 1-octene; saturated carboxylic acid vinyl esters such as vinyl acetate; acrylic acid alkyl esters such as methyl acrylate and ethyl acrylate; methacrylic acid alkyl esters such as methyl methacrylate and ethyl methacrylate; chlorine-containing vinyl monomers such as vinyl chloride and vinylidene chloride; fluorine-containing vinyl monomers such as vinyl fluoride and vinylidene fluoride; unsaturated nitriles such as acrylonitrile and methacrylonitrile; aromatic vinyl monomers such as styrene and α-methyl styrene; and itaconic acid alkyl esters. These ethylenically unsaturated monomers can be used singly or in combination of two or more. Further, when the carboxy group-containing polymer is a copolymer of α,β-monoethylenically unsaturated carboxylic acid and saturated carboxylic acid vinyl esters such as vinyl acetate, the copolymer can be saponified to convert a saturated carboxylic acid vinyl ester unit into a vinyl alcohol unit.

Examples of the carboxy group-containing polysaccharides include acidic polysaccharides having carboxy groups in the molecule, such as alginic acid, carboxymethylcellulose and pectin. These acidic polysaccharides can be used singly or in combination of two or more. Furthermore, the acidic polysaccharides can also be used in combination with a (co)polymer of α,β-monoethylenically unsaturated carboxylic acid.

When the carboxy group-containing polymer (a) is a copolymer of α,β-monoethylenically unsaturated carboxylic acid and other ethylenically unsaturated monomers, the ratio of the molar amount of α,β-monoethylenically unsaturated carboxylic acid monomer to the total molar amount of these monomers in the copolymer is preferably 60 mol % or greater, more preferably 80 mol % or greater, and particularly preferably 90 mol % or greater from the viewpoint of gas barrier properties, hot water resistance and water vapor resistance of the obtained film.

The carboxy group-containing polymer (a) is preferably a homopolymer or a copolymer obtained by polymerizing only α,β-monoethylenically unsaturated carboxylic acid since it is excellent in gas barrier properties, moisture resistance, water resistance, hot water resistance and water vapor resistance and easily forms films excellent in gas barrier properties under high humidity conditions. When the carboxy group-containing polymer (a) is a (co)polymer composed of only α,β-monocthylenically unsaturated carboxylic acid, preferred examples thereof include a homopolymer or a copolymer obtained by polymerizing at least one α,β-monoethylenically unsaturated carboxylic acid selected from the group consisting of acrylic acid, methacrylic acid, crotonic acid, maleic acid, fumaric acid and itaconic acid, and mixtures of two or more thereof. Among these, a homopolymer and a copolymer of at least one α,β-monoethylenically unsaturated carboxylic acid selected from the group consisting of acrylic acid, methacrylic acid and maleic acid is more preferred.

As the carboxy group-containing polymer (a), polyacrylic acid, polymethacrylic acid, polymaleic acid, and mixtures of two or more thereof are particularly preferred. As the acidic polysaccharides, alginic acid is preferred. Among these, polyacrylic acid is particularly preferred since it is relatively easy to obtain and easy to form films excellent in various physical properties.

From the viewpoint of film formation capability and physical properties of films, the number average molecular weight of the carboxy group-containing polymer (a) is preferably in the range of 2,000 to 10,000,000, more preferably in the range of 5,000 to 1,000,000, and still more preferably in the range of 10,000 to 500,000, but not limited thereto.

The “number average molecular weight” herein refers to a value obtained by measurement using gel permeation chromatography (GPC). In GPC measurement, the number average molecular weight of a polymer is measured, in general, relative to a polystyrene standard.

[Polyvalent Metal-Containing Particles (b)]

The polyvalent metal-containing particles (b) contained in the coating layer 3 are preferably particles containing one or more polyvalent metals in which the valence of metal ions is 2 or more. The polyvalent metal-containing particles (b) may be particles made of a polyvalent metal in which the valence of metal ions is 2 or more, particles made of a compound of a polyvalent metal in which the valence of metal ions is 2 or more, or a mixture thereof.

Specific examples of the polyvalent metal include, but are not limited to, metals in the short-period group 2A of the periodic table, such as beryllium, magnesium and calcium; transition metals such as titanium, zirconium, chromium, manganese, iron, cobalt, nickel, copper and zinc; and aluminum.

The polyvalent metal is preferably a divalent metal. Further, the polyvalent metal preferably forms a compound.

Specific examples of the polyvalent metal compound include, but are not limited to, oxides, hydroxides, carbonates, organic acid salts and inorganic acid salts of polyvalent metal. Examples of the organic acid salts include, but are not limited to, acetates, oxalates, citrates, lactates, phosphates, phosphites, hypophosphites, stearates and monoethylenically unsaturated carboxylates. Examples of the inorganic acid salts include, but are not limited to, chlorides, sulfates and nitrates. Alkyl alkoxides of polyvalent metal can also be used as a polyvalent metal compound. These polyvalent metal compounds can be used singly or in combination of two or more.

Among the polyvalent metal compounds, compounds of beryllium, magnesium, calcium, copper, cobalt, nickel, zinc, aluminum and zirconium are preferred from the viewpoint of gas barrier properties of the gas barrier laminate 10, and compounds of divalent metals such as beryllium, magnesium, calcium, copper, zinc, cobalt and nickel are more preferred.

Examples of preferred divalent metal compounds include oxides such as zinc oxide, magnesium oxide, copper oxide, nickel oxide and cobalt oxide; carbonates such as calcium carbonate; organic acid salts such as calcium lactate, zinc lactate and calcium acrylate; and alkoxides such as magnesium methoxide. In one example, the coating layer 3 preferably contains at least one of a zinc compound and a calcium compound.

Polyvalent metals or polyvalent metal compounds are used as particles. The polyvalent metal-containing particles (b) preferably have the mean particle size in the coating liquid in the range of 10 nm to 10 μm (or 10,000 nm) from the viewpoint of dispersion stability of coating liquid used for forming the coating layer 3 (hereinafter, referred to as “coating liquid for forming a coating layer” or simply “coating liquid”), which will be described later, and gas barrier properties of the gas barrier laminate 10. The polyvalent metal-containing particles (b) more preferably have the mean particle size in the coating liquid in the range of 12 nm to 1 μm (or 1,000 nm), still more preferably in the range of 15 nm to 500 nm, and particularly preferably in the range of 15 nm to 50 nm.

If the mean particle size of the polyvalent metal-containing particles (b) is too large, the uniformity of film thickness of the coating layer 3, the surface flatness and the ionic crosslinking reactivity with the carboxy group-containing polymer (a) tend to be insufficient. If the mean particle size of the polyvalent metal-containing particles (b) is too small, the ionic crosslinking reaction with the carboxy group-containing polymer (a) may proceed prematurely. Further, if the mean particle size of the polyvalent metal-containing particles (b) is too small, it may be difficult to uniformly disperse them in the coating liquid.

When the sample is a dry solid, the mean particle size of the polyvalent metal-containing particles (b) can be measured by measuring and counting using a scanning electron microscope or a transmission electron microscope. The mean particle size of the polyvalent metal-containing particles (b) in the coating liquid can be measured by light scattering method [Reference: “Microparticle Engineering System” Vol. I, pp. 362-365, Fuji Techno System (2001)].

The polyvalent metal-containing particles in the coating liquid may be present as primary particles, secondary particles, or a mixture thereof, but in many cases, they are presumed to be present as secondary particles in view of the mean particle size.

[Surfactant (c)]

The coating layer 3 contains a surfactant (c) in order to enhance dispersion of the polyvalent metal-containing particles (b). Surfactants are compounds having both hydrophilic groups and lipophilic groups in the molecule. Surfactants include anionic surfactants, cationic surfactants, amphoteric ionic surfactants and nonionic surfactants. Any surfactants may be used as the coating layer 3.

Examples of anionic surfactants include carboxylic acid type, sulfonic acid type, sulfate ester type and phosphate ester type. Examples of the carboxylic acid type anionic surfactants include aliphatic monocarboxylate, polyoxyethylene alkyl ether carboxylate, N-acyl sarcosine and N-acyl glutaminate. Examples of the sulfonic acid type anionic surfactants include dialkyl sulfosuccinate, alkanesulfonate, alpha olefin sulfonate, linear alkylbenzene sulfonate, alkyl (branched-chain) benzene sulfonate, naphthalene sulfonate-formaldehyde condensates, alkylnaphthalene sulfonate and N-methyl-N-acyl taurate. Examples of the sulfate ester type anionic surfactants include alkyl sulfate, polyoxyethylene alkyl ether sulfate and oil and fat sulfate esters. Examples of the phosphate ester type anionic surfactants include alkyl phosphate type, polyoxyethylene alkyl ether phosphate and polyoxyethylene alkyl phenyl ether phosphate.

Examples of the cationic surfactants (c) include alkylamine salt type and quaternary ammonium salt type. Examples of the alkylamine salt type cationic surfactants include monoalkylamine salts, dialkylamine salts and trialkylamine salts. Examples of the quaternary ammonium salt type cationic surfactants include halogenated (chlorinated, brominated or iodized) alkyltrimethylammonium salts and alkylbenzalkonium chloride.

Examples of the amphoteric surfactants include carboxybetaine type, 2-alkylimidazoline derivative type, glycine type and amine oxide type. Examples of the carboxybetaine type amphoteric surfactants include alkylbetaines and fatty acid amidopropylbetaines. Examples of the 2-alkylimidazoline derivative type amphoteric surfactants include 2-alkyl-N-carboxymethyl-N-hydroxyethylimidazolinium betaines. Examples of the glycine type amphoteric surfactants include alkyl or dialkyl diethylenetriaminoacetic acids. Examples of the amine oxide type amphoteric surfactants include alkyl amine oxides.

Examples of the nonionic surfactants include ester type, ether type, ester ether type and alkanolamide type. Examples of the ester type nonionic surfactant include glycerin fatty acid esters, sorbitan fatty acid esters and sucrose fatty acid esters. Examples of the ether type nonionic surfactant include polyoxyethylene alkyl ethers, polyoxyethylene alkyl phenyl ethers and polyoxyethylene polyoxypropylene glycols. Examples of the ester ether type nonionic surfactant include fatty acid polyethylene glycols and fatty acid polyoxyethylene sorbitans. Examples of the alkanolamide type nonionic surfactant include fatty acid alkanolamides.

Surfactants having polymer skeletons such as styrene-acrylic acid copolymers can also be used.

Among these surfactants, anionic surfactants such as phosphate esters and surfactants having polymer skeletons such as styrene-acrylic acid copolymers are preferred.

[Silicon-Containing Compound (d)]

The coating layer 3 preferably contain a silicon-containing compound (d) in order to improve peeling strength. The silicon-containing compound (d) is at least one compound selected from the group consisting of a silane coupling agent represented by the following general formula (1), a silane coupling agent represented by the following general formula (2), a hydrolysate thereof and a condensate thereof.

Si(OR₁)3Z₁ (1)

Si(R₂)(OR₃)₂Z₂ (2)

In general formula (1), R₁ is an alkyl group having 1 to 6 carbon atoms, which may be the same or different, and Z₁ is an organic group containing an epoxy group or an amino group. In general formula (2), R₂ is a methyl group, R₃ is an alkyl group having 1 to 6 carbon atoms, which may be the same or different, and Z₂ is an organic group containing an epoxy group or an amino group.

Silane coupling agents readily cause hydrolysis and readily cause condensation reactions in the presence of acids or alkalis. Therefore, in the coating layer 3, the silicon-containing compound (d) is rarely present only in the form of a silane coupling agent represented by general formula (1) or (2), only in the form of a hydrolysate thereof, or only in the form of a condensate thereof. That is, in the coating layer 3, the silicon-containing compound (d) is present as a mixture of at least one of a silane coupling agent represented by general formula (1) and a silane coupling agent represented by general formula (2), a hydrolysate thereof, and a condensate thereof.

Each of R₁ and R₃ in general formulas (1) and (2) may be an alkyl group having 1 to 6 carbon atoms, and preferably a methyl group or an ethyl group. Z₁ and Z₂ may be, for example, an organic group having a glycidyloxy group, or an aminoalkyl group.

Specific examples of the silane coupling agent represented by general formula (1) or (2) include 2-(3,4-epoxycyclohexyl)ethyltrimethoxysilane, 3-glycidoxypropylmethyldimethoxysilane, 3-glycidoxypropyltrimethoxysilane, 3-Specific examples of the silane coupling agent represented by general formula (1) glycidoxypropylmethyldiethoxysilane, 3-glycidoxypropyltriethoxysilane, aminopropyltrimethoxysilane and aminopropyltriethoxysilane, and preferred examples are 3-glycidoxypropylmethyldimethoxysilane and 3-glycidoxypropyltrimethoxysilane. These silane coupling agents may be used singly or in combination of two or more.

The hydrolysate of the silane coupling agent represented by general formula (1) or (2) may be a partial hydrolysate, a complete hydrolysate, or a mixture thereof.

The condensate that can be contained, as at least part of the silicon-containing compound (d), in the coating layer 3 is two or more of a hydrolyzed condensate of the silane coupling agent represented by general formula (1), a hydrolyzed condensate of the silane coupling agent represented by general formula (2), and a condensate of a hydrolysate of the silane coupling agent represented by general formula (1) and a hydrolysate of the silane coupling agent represented by general formula (2). These hydrolyzed condensates are produced by the following reactions. That is, first, a silane coupling agent is hydrolyzed. This causes one or more of the alkoxy groups contained in the molecule of the silane coupling agent to be replaced with hydroxy groups, producing a hydrolysate. Further, condensation of the hydrolysate produces a compound in which silicon atoms (Si) are bonded via oxygen. Such condensation is repeated to obtain a hydrolyzed condensate.

### [Composition]

The composition of the coating layer 3 will be described below. When the coating layer 3 is a laminate unit composed of a plurality of layers, the composition of the coating layer 3 described herein refers to the composition as the laminate unit.

The coating layer 3 preferably contains the carboxy group-containing polymer (a) and the polyvalent metal-containing particles (b) at the blending ratio described below.

In an embodiment of the present invention, a ratio ((bₜ)/(aₜ)) (hereinafter, also referred to as an equivalent ratio) of a product (bₜ) of the molar amount and the valence of the polyvalent metal contained in the polyvalent metal-containing particles (b) to the molar amount (aₜ) of the carboxy groups contained in the carboxy group-containing polymer (a) is preferably 0.4 or greater. This ratio is more preferably 0.8 or greater, and particularly preferably 1.0 or greater. The upper limit of the ratio is typically 15.0 or less. When the coating layer 3 is a single layer, the equivalent ratio (bₜ)/(aₜ) is preferably 10.0 or less, and more preferably 2.0 or less. If the ratio is too small, various properties of the gas barrier laminate 10, such as gas barrier properties, hot water resistance and water vapor resistance, tend to deteriorate.

The equivalent ratio can be determined, for example, as follows. The following description will be given of a case where the carboxy group-containing polymer (a) is polyacrylic acid, and the polyvalent metal compound particles (b) are magnesium oxide particles.

The molecular weight of the monomer unit of polyacrylic acid is 72, with one carboxy group per monomer molecule. Therefore, the amount of carboxy groups in 100 g of polyacrylic acid is 1.39 mol. The above equivalent ratio in the coating liquid containing 100 g of polyacrylic acid being 1.0 means that the coating layer 3 contains magnesium oxide in the amount that neutralizes 1.39 mol of carboxy groups. Accordingly, in order to set the above equivalent ratio in the coating layer 3 containing 100 g of polyacrylic acid to 0.6, magnesium oxide in the amount that neutralizes 0.834 mol of carboxy groups may be added to the coating layer 3. Here, the magnesium is divalent, and the molecular weight of magnesium oxide is 40. Therefore, in order to set the above equivalent ratio in the coating layer 3 containing 100 g of polyacrylic acid to 0.6, 16.68 g (0.417 mol) of magnesium oxide may be added to the coating layer 3.

The surfactant (c) is used in an amount sufficient to disperse the polyvalent metal-containing particles in the coating liquid in a stable manner. Therefore, the blending amount of the surfactant (c) in the coating liquid, described as a concentration in the coating liquid for forming a coating layer, is typically in the range of 0.0001 to 70 mass %, preferably in the range of 0.001 to 60 mass %, and more preferably in the range of 0.1 to 50 mass %.

If the surfactant (c) is not added, it is difficult to disperse the polyvalent metal-containing particles (b) in the coating liquid with a sufficiently small mean particle size. As a result, a coating liquid in which the polyvalent metal-containing particles (b) are uniformly dispersed is difficult to obtain. In this case, the coating layer 3, which is obtained by applying and drying a coating liquid on the inorganic vapor deposition layer 2, is difficult to have a uniform film thickness.

From the viewpoint of achieving high gas barrier properties and transparency in the gas barrier laminate 10, the coating layer 3 preferably contains the silicon-containing compound (d) in an amount at which a molar ratio (dt)/(at) of the molar amount (dt) of the silicon-containing compound (d) to the molar amount (at) of the carboxy groups contained in the carboxy group-containing polymer (a) is 0.15% or greater and 6.10% or less. The (dt) in the molar ratio (dt)/(at) is the molar amount of the silicon-containing compound (d) converted into the silane coupling agent.

If the amount of the silicon-containing compound (d) added is too small and the above molar ratio (dt)/(at) is less than 0.15%, the gas barrier laminate 10 tends to have reduced peeling strength. As a result, careful handling is required to prevent interlayer delamination, which causes a decrease in productivity.

From the above viewpoint, the molar ratio (dt)/(at) of the molar amount (dt) of the silicon-containing compound (d) to the molar amount (at) of the carboxy groups contained in the carboxy group-containing polymer (a) is preferably 0.3% or greater, preferably 0.46% or greater, and more preferably 0.61% or greater.

On the other hand, if the amount of the silicon-containing compound (d) added is too large and the above molar ratio (dt)/(at) is greater than 6.10%, the gas barrier laminate 10 tends to have reduced transparency. The silicon-containing compound (d) does not have gas barrier properties. Therefore, if the above molar ratio (dt)/(at) is greater than 6.10%, not only the transparency but also the gas barrier properties of the laminate tend to be reduced.

From the above viewpoint, the molar ratio (dt)/(at) of the molar amount (dt) of the silicon-containing compound (d) to the molar amount (at) of the carboxy groups contained in the carboxy group-containing polymer (a) is preferably 4.57% or less, preferably 3.66% or less, and more preferably 2.13% or less.

The film thickness of the coating layer 3 is preferably 230 nm or greater and 600 nm or less from the viewpoint of achieving both transparency and gas barrier properties. The film thickness of the coating layer 3 is specifically measured by a method of measuring a film thickness of the coating layer, described later. When the coating layer 3 is composed of a plurality of layers, the film thickness of the coating layer 3 described herein refers to the total film thickness. The film thickness of the coating layer 3 is preferably 250 nm or greater and 500 nm or less, and more preferably 300 nm or greater and 450 nm or less.

### <Inorganic Vapor Deposition Layer>

The gas barrier laminate 10 according to the present embodiment includes the inorganic vapor deposition layer 2 between the substrate 1 and the coating layer 3. This further improves the gas barrier properties of the gas barrier laminate 10 having the coating layer 3, achieving both transparency and high gas barrier properties.

The inorganic vapor deposition layer 2 contains an inorganic oxide. Examples of the inorganic oxide include aluminum oxide, silicon oxide, magnesium oxide and tin oxide. Among these, from the viewpoint of achieving both transparency and gas barrier properties, aluminum oxide, silicon oxide, magnesium oxide, or a mixture of two or more thereof is preferred.

The inorganic vapor deposition layer 2 may have a thickness in the range of, for example, 5 nm to 100 nm, and preferably in the range of 10 nm to 50 nm. From the viewpoint of forming a uniform thin film, 5 nm or greater is preferred as a thickness of the inorganic vapor deposition layer 2. When the thin film as a gas barrier material is uniform, it can fully perform functions required of the gas barrier material. From the viewpoint of flexibility of a thin film, 100 nm or less is preferred as a thickness of the inorganic vapor deposition layer 2. When the gas barrier material has poor flexibility, cracking may occur due to external factors such as bending or stretching.

### <Substrate>

The substrate 1 included in the gas barrier laminate 10 according to the present embodiment is not particularly limited, and various types can be used. The materials constituting the substrate 1 are not particularly limited, and various types can be used, such as plastics, paper, and the like.

The substrate 1 may be a single layer made of a single material or may be a multilayer made of multiple materials. Examples of the multilayer substrate includes a substrate in which a film made of plastic is laminated on paper.

In particular, plastic is preferred as the material of the substrate 1 since it can be formed into various shapes and can be used for various applications by providing gas barrier properties.

Examples of the plastics include, but are not particularly limited to, polyolefin resins such as polyethylene and polypropylene; polyester resins such as polyethylene terephthalate, polyethylene-2,6-naphthalate, polybutylene terephthalate, and copolymers thereof; polyamide resins such as nylon-6, nylon-66, nylon-12, metaxylylene adipamide, and copolymers thereof; styrene resins such as polystyrene, styrene-butadiene copolymer and styrene-butadiene-acrylonitrile copolymer; poly(meth)acrylate ester; polyacrylonitrile; polyvinyl acetate; ethylene-vinyl acetate copolymer; ethylene-vinyl alcohol copolymer; polycarbonate; polyarylate; regenerated cellulose; polyimide; polyether imide; polysulfone; polyether sulfone; polyether ketone; and ionomer resins.

When the gas barrier laminate is used as a food packaging material, the substrate 1 is preferably made of polyethylene, polypropylene, polyethylene terephthalate, nylon-6 or nylon-66.

As the plastic constituting the substrate 1, these materials may be used singly or in a blend of two or more.

The plastic may contain additives. Additives can be appropriately selected, depending on the application, from known additives such as pigments, antioxidants, antistatic agents, ultraviolet absorbers and lubricants. The additives may be used singly or in combination of two or more.

The form of the substrate 1 is not particularly limited, and examples thereof include a film, a sheet, a cup, a tray, a tube and a bottle. Among these, a film is preferred.

When the substrate 1 is a film, the film may be a stretched film or an unstretched film.

Although the thickness of the film is not particularly limited, but from the viewpoint of mechanical strength and processability of the obtained gas barrier laminate, it is preferably in the range of 1 μm to 200 μm, and more preferably in the range of 5 μm to 100 μm.

The surface of the substrate 1 may be subjected to plasma treatment, corona treatment, ozone treatment, flame treatment or radical activation treatment with UV or electron beams, so that the coating liquid can be applied without being repelled by the substrate. The treatment method is appropriately selected depending on the type of the substrate.

### [Other Layers]

The gas barrier laminate according to the present embodiment may further include, if necessary, one or more layers other then the substrate 1, the inorganic vapor deposition layer 2 and the coating layer 3.

For example, the gas barrier laminate according to the present embodiment may include only the coating layer 3 described above as the gas barrier coating layer, but may further include one or more layers in addition to the coating layer 3. For example, a layer made of an inorganic compound such as aluminum oxide, silicon oxide or aluminum may be formed on a surface of the substrate by sputtering, ion plating, or the like.

Further, the gas barrier laminate according to the present embodiment may further include an anchor coat layer between the substrate 1 and the inorganic vapor deposition layer 2 or between the inorganic vapor deposition layer 2 and the coating layer 3 in order to enhance adhesion between layers or apply the coating liquid for forming a coating layer without being repelled by the inorganic vapor deposition layer.

FIG. 2 is a cross-sectional view schematically illustrating a gas barrier laminate according to a second embodiment of the present invention. A gas barrier laminate 20 shown in FIG. 2 includes an anchor coat layer 4 between the substrate 1 and the inorganic vapor deposition layer 2, unlike the gas barrier laminate 10 according to the first embodiment described above.

The anchor coat layer 4 can be formed by a conventional method using a known anchor coat liquid. Examples of the anchor coat liquid include those containing resins such as polyurethane resin, acrylic resin, melamine resin, polyester resin, phenol resin, amino resin and fluorine resin.

The anchor coat liquid may further contain an isocyanate compound in addition to resins in order to improve adhesiveness and hot water resistance. The isocyanate compound having one or more isocyanate groups in the molecule can be used, and examples of the isocyanate compound include hexamethylene diisocyanate, xylylene diisocyanate, isophorone diisocyanate and tolylene diisocyanate.

The anchor coat liquid may further contain a liquid medium for dissolving or dispersing the resin and the isocyanate compound.

The thickness of the anchor coat layer 4 is not particularly limited. The thickness of the anchor coat layer 4 may be, for example, in the range of 0.01 μm to 2 μm, and preferably in the range of 0.05 μm to 1 μm. If the film thickness is less than 0.01 μm, it may be too thin to perform the performance as the anchor coat layer. On the other hand, the film thickness of 2 μm or less is preferred from the viewpoint of flexibility. As the flexibility decreases, cracking may occur in the anchor coat layer due to external factors.

The gas barrier laminate according to the present embodiment may further include, if necessary, another layer laminated via an adhesive on the coating layer 3 or on a surface of the substrate 1 or the inorganic vapor deposition layer 2, or may further include another layer formed by extrusion lamination of an adhesive resin.

These other layers to be laminated are not particularly limited and can be appropriately selected according to the purpose of imparting strength, sealability, ease of opening when sealing, design, light shielding, moisture resistance, and the like, and can be made of, for example, the same materials as the plastics described above for the substrate. In addition, paper, aluminum foil and the like may also be used.

The thickness of the layers to be laminated is preferably in the range of 1 μm to 1,000 μm, more preferably in the range of 5 μm to 500 μm, still more preferably in the range of 5 μm to 200 μm, and particularly preferably in the range of 5 μm to 150 μm.

The layers to be laminated may be one type or two or more types.

The gas barrier laminate according to the present embodiment may further include a print layer, if necessary. The print layer may be formed on a coat layer provided on the substrate, or may be formed on a surface of the substrate on which a coat layer is not provided. Further, if another layer is laminated, the print layer may be formed on the laminated layer.

### [Method of Producing Gas Barrier Laminate]

The gas barrier laminate according to the present embodiment can be produced by a production method including a step of forming an inorganic vapor deposition layer and a step of forming a coating layer using a coating liquid for forming a coating layer, described later. This production method can further include, if necessary, a step of forming other layers such as an anchor coat layer and/or a step of forming a print layer, and the like.

As an example of the method of producing a gas barrier laminate according to the present embodiment, a method of producing the gas barrier laminate 20 shown in FIG. 2 will be described below. In the production method described below, the coating layer 3 is composed of a single layer.

In the method of producing the gas barrier laminate 20, the anchor coat layer 4 is formed on the substrate 1. The anchor coat layer 4 can be formed by applying the above anchor coat liquid onto the substrate 1, and drying the formed coating film. The method of applying the anchor coat liquid is not particularly limited, and known printing methods such as offset printing, gravure printing and silk screen printing and known coating methods such as roll coating, knife edge coating and gravure coating can be used. By drying the formed coating film, removal of the solvent and curing proceed, and the anchor coat layer 4 is formed.

In the method of producing the gas barrier laminate 20, the inorganic vapor deposition layer 2 is formed on the anchor coat layer 4. Various methods are known for forming the inorganic vapor deposition layer 2, such as vacuum deposition, sputtering, ion plating and chemical vapor deposition (CVD). Any method can be used, but vapor deposition is typically used.

As a heating means for a vacuum deposition device, there are an electron beam heating method, a resistance heating method, an induction heating method, and the like, and any method can be used.

Further, in order to improve the adhesion of the inorganic vapor deposition layer 2 to the anchor coat layer 4 and the density of the inorganic vapor deposition layer 2, a plasma assisted method or an ion beam assisted method can be used.

Moreover, in order to increase the transparency of the inorganic vapor deposition layer 2, reactive deposition may be performed by blowing oxygen gas or the like during vapor deposition.

In the method of producing the gas barrier laminate 20, the coating layer 3 is formed on the inorganic vapor deposition layer 2. The coating layer 3 can be formed by applying a coating liquid for forming a coating layer prepared by the method described below onto the inorganic vapor deposition layer 2 and drying the formed coating film.

### Method of Preparing Coating Liquid for Forming Coating Layer

In a coating liquid for forming a coating layer, an organic solvent (e) is used as a solvent or a dispersion medium. That is, the coating liquid is a dispersion containing the carboxy group-containing polymer (a), the polyvalent metal-containing particles (b), the surfactant (c) and the organic solvent, and the polyvalent metal-containing particles (b) are dispersed in the coating liquid. In one embodiment, it is preferred that the coating liquid for forming a coating layer further contains the silicon-containing compound (d). The following description will be given of a method of preparing a coating liquid for forming a coating layer containing the silicon-containing compound (d), which is an optional component.

The organic solvent (e) is used in an amount sufficient to uniformly dissolve the carboxy group-containing polymer (a) and uniformly disperse the polyvalent metal-containing particles. Therefore, the organic solvent used is one that dissolves the carboxy group-containing polymer but does not substantially dissolve the polyvalent metal compound and can disperse it in the form of particles.

Further, as the organic solvent (e), a polar organic solvent that dissolves the carboxy group-containing polymer (a) is typically used, but an organic solvent having no polar groups (heteroatoms or atomic groups having heteroatoms) may also be used together with a polar organic solvent.

Examples of the organic solvent (e) that can be preferably used include alcohols such as methanol, ethanol, isopropanol, n-propanol and n-butanol; and polar organic solvents such as dimethyl sulfoxide, N, N-dimethylacetamide, N,N-dimethylformamide, N-methyl-2-pyrrolidone, tetramethylurea, hexamethylphosphoric triamide, and γ-butyrolactone.

In addition to the above polar organic solvents, hydrocarbons such as benzene, toluene, xylene, hexane, heptane and octane; ketones such as acetone and methyl ethyl ketone; halogenated hydrocarbons such as dichloromethane; esters such as methyl acetate; and ethers such as diethyl ether can be appropriately used as the organic solvent (e). Hydrocarbons having no polar groups, such as benzene, are usually used in combination with polar organic solvents.

The coating liquid may contain only the organic solvent (e) as a solvent or a dispersion medium, but may further contain water. Containing water increases solubility of the carboxy group-containing polymer (a) and improves coatability and workability of the coating liquid. The water content of the coating liquid by mass fraction may be 100 ppm or greater, preferably 1,000 ppm or greater, more preferably 1,500 ppm or greater, and still more preferably 2,000 ppm or greater.

The water content of the coating liquid by mass fraction is preferably 50,000 ppm or less, more preferably 10,000 ppm or less, and still more preferably 5,000 ppm or less.

In preparation of a coating liquid for forming a coating layer, a carboxy group-containing polymer solution is prepared by uniformly dissolving the carboxy group-containing polymer (a) in the organic solvent (e), and then adding the silicon-containing compound (d) to the mixture.

Meanwhile, a dispersion is prepared by mixing the polyvalent metal-containing particles (b), the surfactant (c) and the organic solvent (e), and the mixture is subjected to dispersion treatment, if necessary. The dispersion treatment is performed to make the mean particle size of the polyvalent metal-containing particles (b) become a predetermined value. If the mean particle size of the polyvalent metal-containing particles (b) in the mixed solution before dispersion treatment is 10 μm or less, dispersion treatment may be omitted, but even in this case, it is preferred to perform dispersion treatment. Performing the dispersion treatment releases the aggregation of the polyvalent metal-containing particles (b), which stabilizes the coating liquid and increases transparency of the gas barrier laminate obtained by applying the coating liquid. Furthermore, when the coating liquid is applied and the coating film is dried, crosslinking between the carboxy group-containing polymer (a) and the polyvalent metal ions derived from the polyvalent metal-containing particles (b) tends to proceed, and a gas barrier laminate having good gas barrier properties tends to be obtained.

Examples of the dispersion treatment include methods using a high-speed agitator, a homogenizer, a ball mill or a bead mill. In particular, when dispersion is performed using a ball mill or a bead mill, dispersion can be performed with high efficiency, and the coating liquid having a stable dispersion state can be obtained in a relatively short time. In this case, the balls or beads preferably have a small diameter, such as 0.1 mm to 1 mm.

The carboxy group-containing polymer solution prepared as above and the dispersion of the polyvalent metal-containing particles (b) can be mixed together to prepare a coating liquid. In addition, although the silicon-containing compound (d) is added in advance to the carboxy group-containing polymer solution in the preparation method described above, the silicon-containing compound (d) may not be necessarily added to the carboxy group-containing polymer solution, and for example, may be added when the carboxy group-containing polymer solution and the dispersion of the polyvalent metal-containing particles (b) are mixed together.

In the above coating liquid, a total concentration of components other than the organic solvent (e) is preferably in the range of 0.1 to 60 mass %, more preferably in the range of 0.5 to 25 mass %, and particularly preferably in the range of 1 to 20 mass % from the perspective of obtaining a coating film and a coating layer at a desired film thickness with high productivity.

The above coating liquid may contain, if necessary, various additives such as other polymers, thickeners, stabilizers, ultraviolet absorbers, anti-blocking agents, softeners, inorganic layered compounds (e.g., montmorrillonite) and colorants (dyes, pigments).

Examples of the method of applying the coating liquid include, but are not limited to, methods using an air-knife coater, a direct gravure coater, gravure offset, an arc gravure coater, a reverse roll coater such as a top-feed reverse coater, a bottom-feed reverse coater or a nozzle-feed reverse coater, a five-roll coater, a lip coater, a bar coater, a bar reverse coater and a die coater.

Examples of the method of drying the coating film include, but are not limited to, natural drying, drying in an oven set at a predetermined temperature, and drying using a dryer attached to a coater, such as an arch dryer, a floating dryer, a drum dryer or an infrared ray dryer.

Drying conditions can be appropriately determined depending on the drying method and the like. For example, in the method of drying in an oven, the drying temperature is preferably in the range of 40° C. to 150° C., more preferably in the range of 45° C. to 150° C., and particularly preferably in the range of 50° C. to 140° C. The drying time varies depending on the drying temperature, but is preferably in the range of 0.5 seconds to 10 minutes, more preferably in the range of 1 second to 5 minutes, and particularly preferably in the range of 1 second to 1 minute.

It is presumed that, during drying or after drying, the carboxy group-containing polymer (a) and the polyvalent metal-containing particles (b) contained in the coating film react to introduce an ion crosslinked structure. In order to sufficiently proceed the ionic crosslinking reaction, it is preferred that the dried film is left to stand for 1 second to 10 days in a relative humidity atmosphere of preferably 20% or higher, and more preferably in the range of 40% to 100%, and under temperature conditions preferably in the range of 5° C. to 200° C., and more preferably in the range of 20° C. to 150° C.

The gas barrier laminate thus obtained is excellent in moisture resistance, water resistance, hot water resistance and water vapor resistance due to ionic crosslinking. Further, the gas barrier laminate is also excellent in gas barrier properties not only under low humidity conditions but also under high humidity conditions. The gas barrier laminate has an oxygen transmission rate measured in accordance with to JIS K-7126 method B (equal-pressure method) and the method described in ASTM D3985, at a temperature of 30° C. and a relative humidity of 70%, is preferably 10 cm3/(m2·day·MPa) or less.

### <Packaging Body and Packaged Article>

A packaging material according to the present embodiment includes the above gas barrier laminate. The packaging material may be used, for example, to produce a packaging body for packaging an article.

A packaging body according to the present embodiment includes the above packaging material.

The packaging body may be formed of the above packaging material, or may include the above packaging material and other members. In the former case, the packaging body may be, for example, a bag formed of the above packaging material. In the latter case, the packaging body may be, for example, a container including the above packaging material as a lid and a container main body of a bottomed tubular shape.

In the packaging body, the above packaging material may be a molded product. As described above, the molded product may be a container such as a bag, or may be a part of a container, such as a lid. Specific examples of the packaging body or a part thereof include bag products, spouted pouches, laminate tubes, infusion bags, container lids and paper containers.

There are no particular limitations on the applications to which the packaging body may be applied. The packaging body can be used for packaging various articles.

The packaged article according to the present embodiment includes the above packaging body and contents contained in the packaging body.

As described above, the above gas barrier laminate has excellent gas barrier properties and transparency. Therefore, packaging materials and packaging bodies including the gas barrier laminate are suitably used as packaging materials and packaging bodies for articles that are easily deteriorated by the influence of oxygen, water vapor, and the like, and especially as packaging materials and packaging bodies for food products containing sulfur. These packaging materials and packaging bodies can also be suitably used as packaging materials and packaging bodies for packaging chemicals such as agricultural chemicals and pharmaceuticals, industrial materials such as medical tools, mechanical parts and precision materials.

When the above gas barrier laminate is subjected to heat sterilization treatment such as boiling treatment or retort treatment, the gas barrier properties and interlayer adhesion do not deteriorate, but tend to increase. Therefore, these packaging materials and packaging bodies may be packaging materials for heat sterilization and packaging bodies for heat sterilization.

The packaging materials for heat sterilization and packaging bodies for heat sterilization are used for packaging articles that are subjected to heat sterilization treatment after packaging.

Examples of the articles that are subjected to heat sterilization treatment after packaging include foods such as curries, stews, soups, sauces and processed meat products.

Examples of the heat sterilization treatment include boiling treatment and retort treatment. The boiling treatment and retort treatment are as described above.

### EXAMPLES

The following description will be given of tests conducted in connection with the present invention.

### <Preparation of Coating Liquid for Forming Coating Layer>

A coating liquid for forming a coating layer was prepared by the following method.

### (Coating Liquid 1)

Polyacrylic acid (PAA) (manufactured by Toagosei Co., Ltd., JURYMER® AC-10LP, number average molecular weight 50,000) was heated and dissolved in 2-propanol to prepare PAA solution 1 at a concentration of 10 mass %.

1.8 g of polyether phosphate ester (manufactured by Kusumoto Chemicals, Ltd., DISPARLON (registered trademark) DA-375, solid content 100 mass %) was dissolved in 26.2 g of 2-propanol. Then, 12 g of zinc oxide (manufactured by Sakai Chemical Industry Co., Ltd., FINEX®-30) having an average primary particle size of 35 nm was added and stirred. The obtained liquid was subjected to dispersion treatment for 1 hour using a planetary ball mill (manufactured by Fritsch, P-7). In this dispersion treatment, zirconia beads with a diameter of 0.2 mm were used. Then, the beads were sieved from the liquid to obtain ZnO dispersion 1 containing zinc oxide at a concentration of 30 mass %.

Then, 56 g of PAA solution 1, 15 g of ZnO dispersion 1, 0.1 g of 3-glycidoxypropyltrimethoxysilane (manufactured by Shin-Etsu Chemical Co., Ltd., KBM-403) as a silane coupling agent (SC agent), and 57.9 g of 2-propanol were mixed to prepare coating liquid 1.

### (Coating Liquid 2)

A coating liquid 2 was prepared in the same manner as with the preparation method of coating liquid 1 except that PAA solution 1 was changed to 38 g and ZnO dispersion 1 was changed to 20 g.

### (Coating Liquid 3-1)

20 g of polyacrylic acid (PAA) aqueous solution (manufactured by Toagosei Co., Ltd., ARON (registered trademark) A-10H, number average molecular weight 200,000, solid content 25 mass %) was dissolved in 58.9 g of distilled water to prepare PAA solution 2.

Then, 0.44 g of aminopropyltrimethoxysilane (manufactured by Sigma-Aldrich Japan LLC) was added and uniformly stirred to prepare coating liquid 3-1.

### (Coating Liquid 3-2)

100 g of aqueous dispersion of zinc oxide fine particles (manufactured by Sumitomo Osaka Cement Co., Ltd., “Z-143”, solid content 30 mass %) and 1 g of a curing agent (“Liofol HAERTER UR 5889-21” manufactured by Henkel) were mixed to obtain coating liquid 3-2.

### (Coating Liquid 4-1)

20 g of polyacrylic acid (PAA) aqueous solution (manufactured by Toagosei Co., Ltd., ARON (registered trademark) A-10H, number average molecular weight 200,000, solid content 25 mass %) was dissolved in 20 g of distilled water to prepare PAA solution 2.

0.6 g of zinc oxide (manufactured by Sakai Chemical Industry Co., Ltd., FINEX®-30) was added to 7 g of distilled water to prepare ZnO dispersion 2.

After the entire amount of ZnO dispersion 2 prepared above was added and dissolved in the entire amount of PAA solution 2 prepared above, 57.12 g of distilled water and 38.1 g of 2-propanol were added to dilute the mixture. Then, 0.44 g of aminopropyltrimethoxysilane (manufactured by Sigma-Aldrich Japan LLC) was added and uniformly stirred to obtain coating liquid 4-1.

### (Coating Liquid 4-2)

1 g of sodium polyacrylate (manufactured by Nippon Shokubai Co., Ltd., AQUALIC YS-100) and 15 g of calcium carbonate (Hakuenka PZ manufactured by Shiraishi Calcium Kaisha, Ltd.) were added to 35 g of distilled water, and the mixture was subjected to dispersion treatment for 1 hour using a planetary ball mill (P-7 manufactured by Fritsch). In this dispersion treatment, zirconia beads with a diameter of 0.2 mm were used. Then, the beads were sieved from the liquid, which was then diluted with distilled water to obtain a dispersion containing sodium polyacrylate at a concentration of 1 mass % and calcium carbonate at a concentration of 15 mass %

The entire amount (100 g) of the obtained dispersion and 1.65 g of a curing agent (manufactured by BASF, “Basonat HW1000”) were mixed to obtain coating liquid 4-2.

### (Coating Liquid C1)

A coating liquid C1 was prepared in the same manner as with the preparation method of coating liquid 1 except that PAA solution 1 was changed to 36 g and ZnO dispersion 1 was changed to 24 g.

### (Coating Liquid C2)

A coating liquid C2 was prepared in the same manner as with the preparation method of coating liquid 1 except that PAA solution 1 was changed to 50 g and ZnO dispersion 1 was changed to 12 g.

### <Preparation of Anchor Coat Layer>

In a dilution solvent (ethyl acetate), 1 part by mass of γ-isocyanatopropyltrimethoxysilane and 5 parts by mass of acrylic polyol were mixed and stirred. Subsequently, tolylene diisocyanate (TDI) was added as an isocyanate compound so that the amount of NCO groups was equal to the amount of OH groups of the acrylic polyol. The obtained mixed solution was diluted with the above diluent solvent at a concentration of 2 mass % to obtain anchor coat liquid 1. The acrylic polyol used was GS-5756 manufactured by Mitsubishi Rayon Co., Ltd.

### <Production of Gas Barrier Laminate>

### Example 1

The anchor coat liquid 1 was applied onto one side of a biaxially stretched polypropylene film (manufactured by Mitsui Chemicals Tohcello, Inc., trade name: ME-1, thickness 20 μm) at a dry thickness of 0.2 μm using a bar coater and dried at 150° C. for 1 minute to form an anchor coat layer. An alumina vapor deposition layer was formed on the anchor coat layer at a thickness of 20 nm using a vapor deposition apparatus.

The coating liquid 1 was applied onto the alumina vapor deposition layer using a bar coater. The coating film was dried in an oven at 50° C. for 1 minute to form a coating layer aₜ a film thickness of 400 nm. Thus, a laminate 1 was obtained.

### Example 2

A laminate 2 was produced in the same manner as with the method in Example 1 except that the coating liquid 1 used for forming a coating layer in Example 1 was changed to the coating liquid 2.

### Example 3

A laminate 3 was produced in the same manner as with the method in Example 2 except that the coating liquid 2 was applied so that the coating layer had a dry thickness of 250 nm.

### Example 4

A laminate 4 was produced in the same manner as with the method in Example 1 except that the coating liquid 1 was applied so that the coating layer had a dry thickness of 550 nm.

### Example 5

The same method as in Example 1 was used until formation of the alumina vapor deposition layer to obtain a laminate composed of substrate layer/anchor coat layer/alumina vapor deposition layer. Then, the coating liquid 3-1 was applied onto the alumina vapor deposition layer at a dry thickness of 200 nm using a bar coater to form a first coating layer. Then, after aging at 50° C. for 48 hours, the coating liquid 3-2 was applied onto the first coating layer using a bar coater and dried in an oven at 50° C. for 1 minute to form a second coating layer at a film thickness of 200 nm. Thus, a laminate 5 was obtained.

### Example 6

A laminate 6 was produced in the same manner as with the method in Example 5 except that the coating liquid 3-1 and the coating liquid 3-2 were changed to the coating liquid 4-1 and the coating liquid 4-2, respectively.

### Comparative Example 1

A laminate 1C was produced in the same manner as with the method in Example 1 except that the coating liquid 1 used for forming a coating layer in Example 1 was changed to the coating liquid C1.

### Comparative Example 2

A laminate 2C was produced in the same manner as with the method in Example 1 except that the coating liquid 1 used for forming a coating layer in Example 1 was changed to the coating liquid C2.

### <Measurement of Film Thickness>

The cross-section of each laminate was observed with a transmission electron microscope, and the film thickness of the coating layer was measured.

### <Measurement of X-Ray Fluorescence Intensity>

The X-ray fluorescence intensity (kcps) of polyvalent metal-containing particles (ZnO or CaCO₃) in the coating layer, which is a surface layer of each laminate, was measured using an X-ray fluorescence analyzer (manufactured by Rigaku Corporation, wavelength-dispersive compact X-ray fluorescence analyzer “Supermini”).

For zinc oxide (ZnO), ZnO-deposited films with film thicknesses of 0.25 nm, 0.18 nm and 0.15 nm were prepared as standard samples (PET on which ZnO is deposited). The X-ray fluorescence (Kα radiation) intensity of Zn was measured for these standard samples, and calibration curves were drawn as 4.8 kcps, 2.1 kcps and 1.2 kcps, respectively. Based on the obtained calibration curve, the X-ray fluorescence (Kα radiation) intensity per unit area of the coating layer was determined.

Detection spectrum: Zn-Kα

X-ray excitation conditions: target Pb, tube voltage 50 kV, tube current 4.00 mA

Spectroscopic crystal: LiF

Detector: SC (scintillation counter)

Calibration curves were similarly produced for calcium carbonate (CaCO₃), and the X-ray fluorescence intensity per unit area of the coating layer was determined.

### <Measurement of UV Absorbance>

An unstretched polypropylene (CPP) film (60 μm thickness) was laminated on the coating layer of each laminate using a two-part type urethane-based adhesive. This was folded with the CPP film inside, and three sides were thermally bonded to form a bag. The obtained bag was filled with water or L-cys aqueous solution (0.3 mass %) as the content, and the remaining one side was sealed by thermal bonding to produce a four-side sealed bag filled with the content. The samples filled with water were subjected to retort treatment at 130° C. for 60 minutes. The samples filled with L-cysteine (L-cys) aqueous solution (0.3 mass %) were subjected to retort treatment at 130° C. for 30 minutes. After the retort treatment, the four-side sealed bags were opened and used as samples for measuring UV absorbance.

The UV absorbance X (abs) of each sample was measured using an ultraviolet-visible spectrophotometer (manufactured by Shimadzu Corporation, ultraviolet-visible spectrophotometer “UV-2450”). The measurement range was set to a wavelength of 300 nm to 550 nm. The absorbance X was obtained by subtracting the absorbance X₂ of the measurement sample at the wavelength of 500 nm from the absorbance X₁ of the measurement sample at the wavelength of 350 nm. Table 1 shows the results.

### <Oxygen Transmission Rate: OTR>

An unstretched polypropylene (CPP) film (60 μm thickness) was laminated on the coating layer of each laminate using a two-part type urethane-based adhesive. This was folded with the CPP film inside, and three sides were thermally bonded to form a bag. The obtained bag was filled with water or L-cys aqueous solution (0.3 mass %) as the content, and the remaining one side was sealed by thermal bonding to produce a four-side sealed bag filled with the content. The samples filled with water were subjected to retort treatment at 130° C. for 60 minutes. The samples filled with L-cys aqueous solution (0.3 mass %) were subjected to retort treatment at 130° C. for 30 minutes.

The oxygen transmission rate (OTR) of each sample after the retort treatment was measured using an oxygen transmission rate measurement device OX-TRAN (registered trademark), manufactured by MOCON Inc., under conditions of a temperature of 30° C. and a relative humidity of 70%. The measurement method was in accordance with JIS K-7126 method B (equal-pressure method) and ASTM D3985, and the measurement values were expressed in units of cc/m2/day/atm. Table 1 shows the results.

TABLE 1

| | | | | | | | | | UV absorbance X | | | | | |
|---|---|---|---|---|---|---|---|---|---|---|---|---|---|---|
| | | Coating liquid | | | | | | | [abs] | | | OTR | | Zn/COOH or |
| | | | Carboxy | Polyvalent | | | X-ray | | Before | | | [cc/m²/day/atm] | | Ca/COOH |
| | | | group- | metal- | Film | | fluorescence | | hot | 130° C./ | 130° C./ | 130° C./ | 130° C./ | (equivalent |
| | Coating | | containing | containing | thickness | | intensity | | water | 60 min/ | 30 min/ | 60 min/ | 30 min/ | ratio |
| | layer | No. | polymer | particles | [nm] | | [kcps] | | treatment | water | L-cys | water | L-cys | be/at) |
| Ex.1 | Single | 1 | PAA | ZnO | 400 | | 4.3 | | 0.35 | 0.02 | 0.02 | <2 | <2 | 1.42 |
| (Laminate 1) | layer | | | | | | | | | | | | | |
| Ex.2 | Single | 2 | PAA | ZnO | 400 | | 7.1 | | 0.45 | 0.20 | 0.18 | <2 | <2 | 2.79 |
| (Laminate 2) | layer | | | | | | | | | | | | | |
| Ex.3 | Single | 2 | PAA | ZnO | 250 | | 4.6 | | 0.33 | 0.03 | 0.02 | <2 | <2 | 2.79 |
| (Laminate 3) | layer | | | | | | | | | | | | | |
| Ex.4 | Single | 1 | PAA | ZnO | 550 | | 5.9 | | 0.39 | 0.06 | 0.06 | <2 | <2 | 1.42 |
| (Laminate 4) | layer | | | | | | | | | | | | | |
| Ex.5 | First | 3-1 | PAA | — | 200 | 400 | 5.5 | | 0.47 | 0.30 | 0.31 | <2 | <2 | 10.62 |
| (Laminate 5) | coating | | | | | | | | | | | | | |
| | layer | | | | | | | | | | | | | |
| | Second | 3-2 | — | ZnO | 200 | | | | | | | | | |
| | coating | | | | | | | | | | | | | |
| | layer | | | | | | | | | | | | | |
| Ex.6 | First | 4-1 | PAA | ZnO | 200 | 400 | 0.5 | 3.4 | 0.1 | 0.02 | 0.02 | <2 | 2 | 3.93 |
| (Laminate 6) | coating | | | | | | | | | | | | | |
| | layer | | | | | | | | | | | | | |
| | Second | 4-2 | PAANa | CaCO₃ | 200 | | 2.9 | | | | | | | |
| | coating | | | | | | | | | | | | | |
| | layer | | | | | | | | | | | | | |

| Comp.Ex.1 | Single | C1 | PAA | ZnO | 400 | 8.3 | 0.5 | 0.25 | 0.25 | 17 | 4 | 3.54 |
|---|---|---|---|---|---|---|---|---|---|---|---|---|
| (Laminate C1) | layer | | | | | | | | | | | |
| Comp.Ex.2 | Single | C2 | PAA | ZnO | 400 | 4.2 | 0.26 | 0.01 | 0.01 | 3 | 3 | 1.27 |
| (Laminate C2) | layer | | | | | | | | | | | |

As seen from Table 1, the gas barrier laminates of Examples 1 to 6 maintain high oxygen barrier properties after moist heat treatment, and even when the contents contain sulfur, suppress deterioration of oxygen barrier properties caused by permeation of sulfur during moist heat treatment.

The present invention is not limited to the embodiments described above, but may be modified in various ways when implemented, without departing from the spirit of the present invention. The embodiments may be appropriately combined in implementation. In this case, the combinations each exert the advantageous effects accordingly. Further, the embodiments described above include various inventions. Therefore, various inventions can be extracted from combinations selected from a plurality of constituent elements disclosed herein. For example, even if some constituent elements are eliminated from all the constituent elements disclosed in the embodiments, the configuration with these constituent elements eliminated can be understood to be within the scope of the invention as long as the issues can be solved and the advantageous effects can be achieved.

[Reference Signs List] 1 . . . . Substrate; 2 . . . . Inorganic vapor deposition layer; 3 . . . . Coating layer; 4 . . . . Anchor coat layer; 10, 20 . . . . Gas barrier laminate.

What is claimed is:

1. A gas barrier laminate, comprising:
a substrate;
an inorganic vapor deposition layer containing an inorganic oxide; and
a coating layer, which are laminated in this order, the coating layer being composed of a single layer or a plurality of layers, wherein
the coating layer contains a carboxy group-containing polymer and at least one type of polyvalent metal-containing particles,
a total X-ray fluorescence intensity of metal elements contained in the polyvalent metal-containing particles is 3.0 kcps or greater and 8.0 kcps or less, and
an absorbance X of the gas barrier laminate obtained by subtracting an absorbance X₂ at a wavelength of 500 nm from an absorbance X₁ at a wavelength of 350 nm measured with an ultraviolet-visible spectrophotometer after hot water treatment at 130° C. for 30 minutes using a 0.3 mass % L-cysteine aqueous solution satisfies the following formula (1):
$$X = {X}_{1} - {X}_{2} \geq 0.02 ( abs ) . \qquad ( 1 )$$

2. The gas barrier laminate of claim 1, wherein
the coating layer is a single layer.

3. The gas barrier laminate of claim 1, wherein
the coating layer includes a laminate unit in which a first coating layer containing the carboxy group-containing polymer and a second coating layer containing the polyvalent metal-containing particles are adjacent to each other.

4. The gas barrier laminate of claim 3, wherein
the first coating layer further contains polyvalent metal-containing particles different from the polyvalent metal-containing particles contained in the second coating layer.

5. The gas barrier laminate of claim 1, wherein
a polyvalent metal contained in the polyvalent metal-containing particles is a divalent metal.

6. The gas barrier laminate of claim 1, wherein
the coating layer contains at least one of a zinc compound and a calcium compound as the polyvalent metal-containing particles.

7. The gas barrier laminate of claim 1, wherein
the carboxy group-containing polymer contains a constituent unit derived from at least one α,β-monoethylenically unsaturated carboxylic acid selected from the group consisting of acrylic acid, methacrylic acid, crotonic acid, itaconic acid, maleic acid and fumaric acid.

8. The gas barrier laminate of claim 1, wherein
the coating layer has a film thickness of 230 nm or greater and 600 nm or less.

9. A packaging body comprising the gas barrier laminate of claim 1.

10. A packaged article, comprising:
the packaging body according to claim 9; and
contents contained in the packaging body.
